(19) United States
(12) Patent Application Publication
(10) Pub. No.: US 2025/0273620 A1
(43) Pub. Date: Aug. 28, 2025

(54) METHOD FOR DIE-TO-DIE HYBRID BONDING USING AN ADVANCED DISTRIBUTION MODEL

(71) Applicants: TOKYO ELECTRON LIMITED, Tokyo (JP); SICLARITY, INC., Sunnyvale, CA (US)

(72) Inventors: H. Jim FULFORD, Marianna, FL (US); Partha MUKHOPADHYAY, Oviedo, FL (US); Zuriel CARIBE, Albany, NY (US); Eric PANNING, Portland, OR (US)

(73) Assignees: TOKYO ELECTRON LIMITED, Tokyo (JP); SICLARITY, INC., Sunnyvale, CA (US)

(21) Appl. No.: 19/061,149

(22) Filed: Feb. 24, 2025

Related U.S. Application Data
(60) Provisional application No. 63/556,980, filed on Feb. 23, 2024.

(51) Int. Cl. H01L 23/00

(52) U.S. Cl. CPC H01L 24/80; H01L 24/74; H01L 2224/74; H01L 2224/80895; H01L 2224/80896; H01L 2224/80948; H01L 2224/80986

(57) ABSTRACT

Aspects of the present disclosure provide a die-to-die hybrid bonding method. The die-to-die hybrid bonding method includes obtaining a metal etch depth profile value for each die from a first group of dies and for each die from a second group of dies, the metal etch depth profile value of each die representing a copper (Cu) recess depth of a bonding region of the respective die; based on the metal etch depth profile values, executing a die pairing process that pairs each die from the first group of dies with a corresponding die from the second group of dies to form a plurality of pairs of dies, an aggregate metal etch depth profile value of each pair of dies being within a predetermined range; and bonding the plurality of pairs of dies through an anneal process.

### CROSS-REFERENCE TO RELATED APPLICATIONS

This present disclosure claims the benefit of U.S. Provisional Application No. 63/556,980, filed on Feb. 23, 2024, which is incorporated herein by reference in its entirety.

### FIELD OF THE INVENTION

The present disclosure relates to semiconductor manufacturing of integrated circuits, and particularly to packaging and stacking of dies as a technique for transistor stacking or 3D formation of semiconductors.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Aspects of the disclosure provide a die-to-die hybrid bonding method. The die-to-die hybrid bonding method includes obtaining a metal etch depth profile value for each die from a first group of dies and for each die from a second group of dies, the metal etch depth profile value of each die representing a copper (Cu) recess depth of a bonding region of the respective die; based on the metal etch depth profile values, executing a die pairing process that pairs each die from the first group of dies with a corresponding die from the second group of dies to form a plurality of pairs of dies, an aggregate metal etch depth profile value of each pair of dies being within a predetermined range; and bonding the plurality of pairs of dies through an anneal process.

Aspects of the disclosure provide a die-to-die hybrid bonding system. The die-to-die hybrid bonding system includes a controller configured to control a measurement system to obtain a metal etch depth profile value for each die from a first group of dies and for each die from a second group of dies, the metal etch depth profile value of each die representing a Cu recess depth of a bonding region of the respective die; based on the metal etch depth profile values, control a die pairing system to perform a die pairing process that pairs each die from the first group of dies with a corresponding die from the second group of dies to form a plurality of pairs of dies, an aggregate metal etch depth profile value of each pair of dies being within a predetermined range; and control an annealing system to execute an anneal process to bond the plurality of pairs of dies.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows a semiconductor wafer (e.g., a 200 mm or 300 mm wafer) according to embodiments of the disclosure;

FIG. 2 shows the semiconductor wafer after a recess process according to embodiments of the disclosure;

FIG. 3A shows a top view of the recessed semiconductor wafer;

FIG. 3B shows a top view of a bonding region of the recessed semiconductor wafer;

FIG. 3C shows a 3D cross-sectional view of the bonding region of the recessed semiconductor wafer;

FIGS. 4A-4B shows a die-to-die bonding process;

FIG. 5 shows a flow chart of the die-to-die bonding process; and

FIG. 6 shows a die-to-die bonding system.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Hybrid bonding can be typically executed at bond wiring levels or structures of two opposing dies (or wafers). The hybrid bonding can involve bonding a die to a die, a die to a wafer, or a wafer to a wafer. Each of the two opposing dies (or wafers) has a bonding region (or a bonding surface) including exposed or uncovered dielectric material and conductive material (e.g., metal). Thus, through the hybrid bonding, the dielectric materials of the bonding regions of the two opposing dies can be bonded together, and the metal materials of the bonding regions of the two opposing dies can be bonded together, resulting in dielectric-to-dielectric bonds and metal-to-metal bonds. The hybrid bonding process involves an annealing process which results in expansion of the metals of the opposing dies so that the metals of the bonding regions of the two opposing dies can be bonded together.

The bonding region can be formed with various wiring techniques. For example, one of the wiring techniques includes forming lines and/or vias in a dielectric material (e.g., silicon oxide), depositing metal using an overfill technique, and then using a planarization process such as chemical-mechanical polishing (CMP) to remove the overburden of the metal. The planarization process removes the overburden of the metal, but also results in the metal having a recessing below a bonding surface (or top surface) of the dielectric. Having the recess can be advantageous because metal bonding can be realized using an annealing process in which the metal expands within its passage and then contacts corresponding metal in an opposing die until a physical connection and bond is established, thereby providing electric connections as well.

The challenge, however, is that variations of the recesses of the metal (e.g., copper Cu) of the bonding region over a surface area of a wafer (such as a 200 mm or 300 mm wafer) are inevitable. Such recess variations can lead to various post-oxide bonding recess gaps in the hybrid bonding. As such, batch annealing under the same temperature and time results in dissimilarities in the metal-to-metal (e.g., Cu-to-Cu) hybrid bonding. The dissimilarities provide either not enough expansion for the metal so that the metal fails to form a connection, or too much expansion causing the metal to enter the bonding surface of the dielectric material, leading to a yield reduction. Moreover, the performance of the bonded dies in terms of electrical characteristics is also compromised.

This disclosure provides methods and techniques of pairing (or matching) dies to be bonded for optimized bonding of batches of dies.

In semiconductor bonding, a pick-and-place process refers to a robotic process of grasping a first die and positioning the first die on a second die for bonding, while aligning points to be connected. The robotic process can be executed by various robots are designed to operate in a cleanroom and to significantly reduce manufacturing time and improve manufacturing quality.

Because the bonding forms a combined circuit that electrically connects both the first and second dies, ensuring that the electrical connections are aligned and properly formed is crucial for a working combined circuit. Accordingly, the techniques herein pair dies to make the combined recess depth as uniform as possible.

For die-to-die bonding, after bonding layers of dielectric and metal of a wafer have been planarized, the wafer is diced or cut to generate separate, individual dies. With a conventional pick-and-place process, a next-in-line die from a group of first dies (or top dies) is picked and placed on a next-in-line die from a group of second dies (or bottom dies). The problem with this process is that metal recess depths of each die vary from die to die, depending on location on the wafer. This is because a center-to-edge dishing issue can happen during the CMP process. For example, for a 300 mm wafer, dies located on the outer edge of the wafer can have a 3 nm average recess depth, while dies located on the center of the wafer can have a 7 nm average recess depth. The corresponding dies for bonding can be sourced from another 300 mm wafer, which is also subject to the center-to-edge dishing issue. With random or blind die selection and/or without the knowledge of the recess depth variability, pair dies can have significant differences in combined recess depths.

For example, if the dies from a top wafer have recess depths that are generally grouped as 3 nm, 6 nm, and 9 nm, and the dies from a bottom wafer can also have 3 nm, 6 nm, and 9 nm of recess depths, then random pairing can result in combined recess depths that range from 6 nm to 18 nm. For example, if two paired dies each having a recess depth of 6 nm are paired, then the combined recess depth (or the gap between the metals of the bonding regions of the top and bottom wafers) of the paired dies is 12 nm. Likewise, if a die having a recess depth of 3 nm and a die having a recess depth of 9 nm are paired, then the combined recess depth of the paired dies is also 12 nm. If, however, two paired dies each having a recess depth of 3 nm are paired, then the combined recess depth of the paired dies is 6 nm, while two paired dies each having a recess depth of 9 nm can have a combined recess depth of 18 nm.

With the combined recess depths ranging from 6 nm to 18 nm among the multiple paired dies, a low bonding yield can be achieved. This is in part because the time and temperature of an anneal process used for pairing the dies are determined based on the expansion of the metals. The time and temperature of the anneal process can only be applicable to a range of combined recess depths in order to achieve a high bonding yield. If the expansion of the metals is out of the range of combined recess depths, the bonding yield may be reduced. In an example, the expansion of the metals is not enough to form a physical or electrical connection between the metals due to the combined recess depth of the metals being larger than a maximum value of the range of combined recess depths (e.g., a maximum allowed combined recess depth of the anneal process). In another example, the expansion of the metals is too much due to the combined recess depth of the metals being smaller than a minimum value of the range of combined recess depths (e.g., a minimum allowed combined recess depth of the anneal process), and the excess metal can spill into the dielectric interface and weaken bonding or create shorts to other adjacent wires. Accordingly, as discovered herein, selective pairing based on combined recess depth results in a better bonding and a higher yield.

Aspects of the disclosure provide a distribution model for a hybrid bonding tool. The distribution model can minimize metal (e.g., copper) recess gap variations by picking the dies from various positions of a wafer to place on corresponding positions of the dies. In one embodiment, the model picks the dies (the top dies) from various positions of the wafer and place them on corresponding positions on the dies (the bottom dies) to maintain the same Cu recess gap at post-oxide-bonding condition after accounting for the CMP recess variations over the full wafer. That way the combined recess gap of the bonded dies across the whole wafer would be the same which allows for baking/annealing of the bonded wafers in a batch under the same condition. Batch annealing is needed for throughput, and normalized gaps are needed for yield. This enables all paired dies to be annealed at the same time and temperature for uniform process conditions.

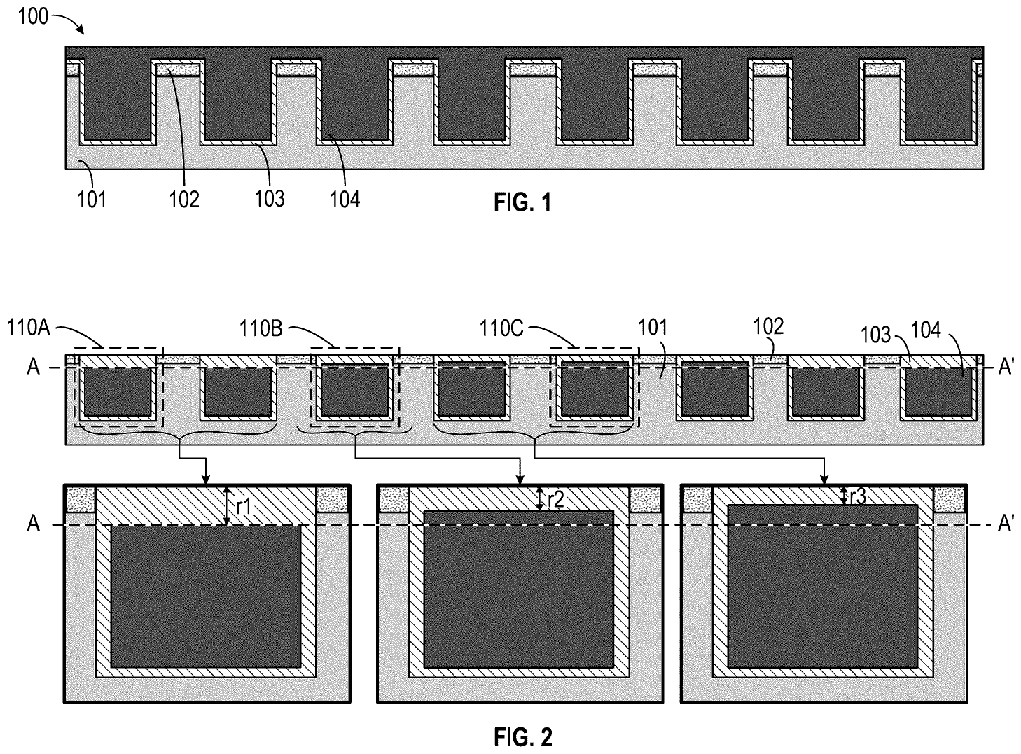

FIG. 1 shows a semiconductor wafer 100 (e.g., a 200 mm or 300 mm wafer) according to embodiments of the disclosure. The semiconductor wafer 100 includes a substrate 101 such as silicon and a first dielectric material 102 formed on the substrate 101. In an example, the first dielectric material can be a thick oxide layer. The semiconductor wafer 100 further includes a liner of a second dielectric material 103 that can be formed by etching the substrate 101 and the first dielectric material 102, for example, using a lithography patterning with a through silicon via (TSV) mask. The semiconductor wafer 100 includes a metal material 104 (e.g., Cu) formed on the liner of the second dielectric material 103. In an example, the metal material 104 can be formed by depositing a metal seed layer through an atomic layer deposition (ALD) process and then electroplating the metal material through an electroplating process.

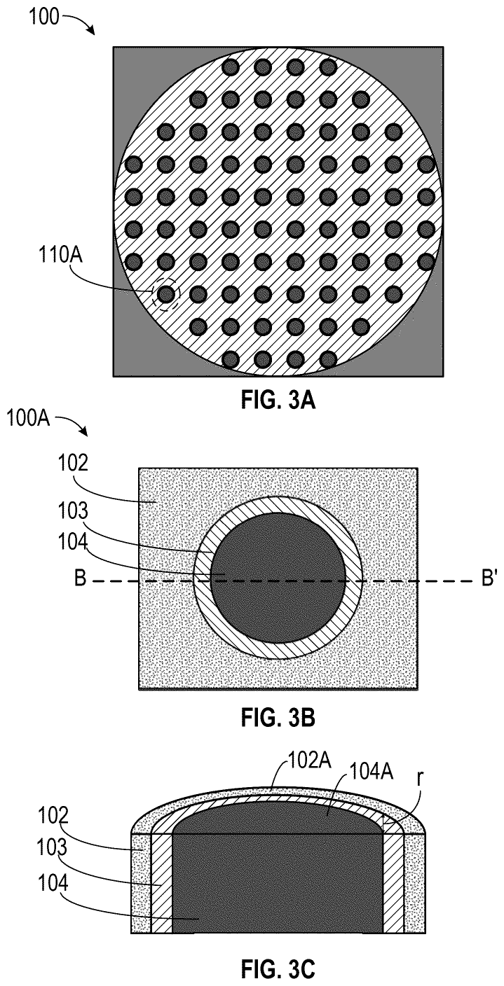

The metal material 104 can be further polished through a chemical-mechanical polishing (CMP) process and recessed with respect to the first dielectric material 102 to form a plurality of bonding regions 110, as shown in FIG. 2. The recess depths (e.g., r1, r2, or r3) of the recessed metal material 104 of the bonding regions 110 are varied over the semiconductor wafer 100. For example, the recess depths of the recessed metal material 104 of the bonding regions 110 can increase from the center of the semiconductor wafer 100 to the edge of the semiconductor wafer 100. As shown in FIG. 2, the recess depth r1 of the bonding region 110A at the edge of the semiconductor wafer 100 is greater than the recess depth r2 of the bonding region 110B, which is greater than the recess depth r3 of the bonding region 110C around the center of the semiconductor wafer 100.

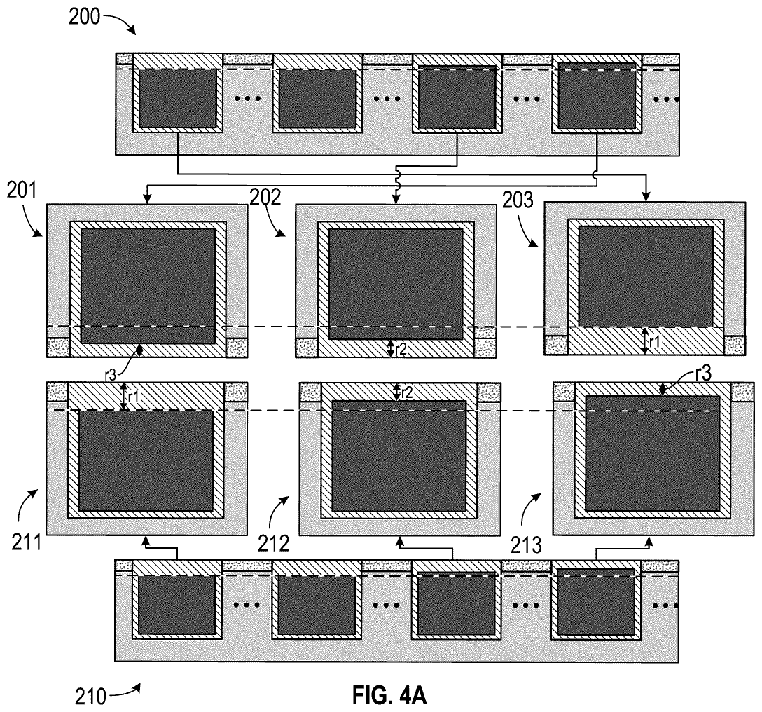

FIG. 3A shows a top view of the semiconductor wafer 100 including the plurality of bonding regions 110, FIG. 3B shows a top view of the bonding region 110A, and FIG. 3C shows a 3D cross-sectional view of the bonding region 110A along the line BB′. As shown in FIG. 3C, the recess depth (or gap) can represent a distance r between a top surface 102A of the first dielectric material 102 and a top surface 104A of the metal material 104.

As described above, for the die-to-die bonding, a bonding region of a top die needs to be bonded with a bonding region of a bottom die, and a total recess gap between two bonding regions needs to be minimized.

This disclosure provides a distribution model that can be used to minimize the total recess gap based on the recess depths of the dies.

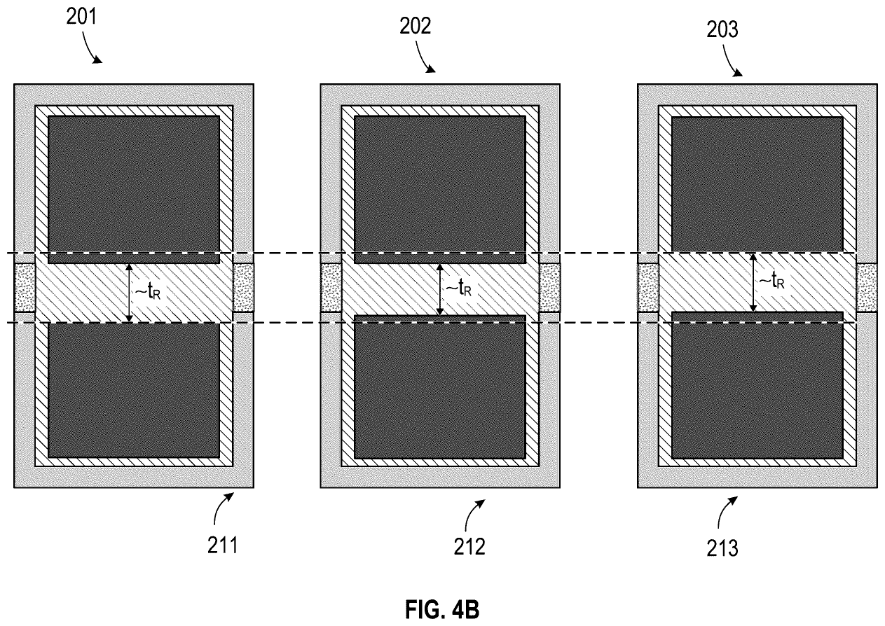

As shown in FIG. 4A, by using the distribution model, the dies from a top wafer 200 can be picked and placed on the dies from a bottom wafer 210 to achieve almost uniform total recess gaps. For example, a first top die 201 having a recess depth of r3 can be picked and placed on a first bottom die 211 having a recess depth of r1 to achieve a total recess gap of r1+r3, a second top die 202 having a recess depth of r2 can be picked and placed on a second bottom die 212 having a recess depth of r2 to achieve a total recess gap of r2+r2, which can be almost equal to r1+r3. Accordingly, after the die-to-die bonding, almost uniform total recess gaps t_{R} can be achieved across the wafers, as shown in FIG. 4B.

In an embodiment, the distribution model can be an artificial intelligence (AI) model that is trained to pair dies from a first group of dies with dies from a second group of dies based on recess depths of the dies, such that an aggregate (or total) recess depth (or gap) of each pair of dies is within a predetermined range. For example, the AI model can be a machine learning model, a neural network model, a transformer model, a large language model, and the like, or a combination of any two or more AI models.

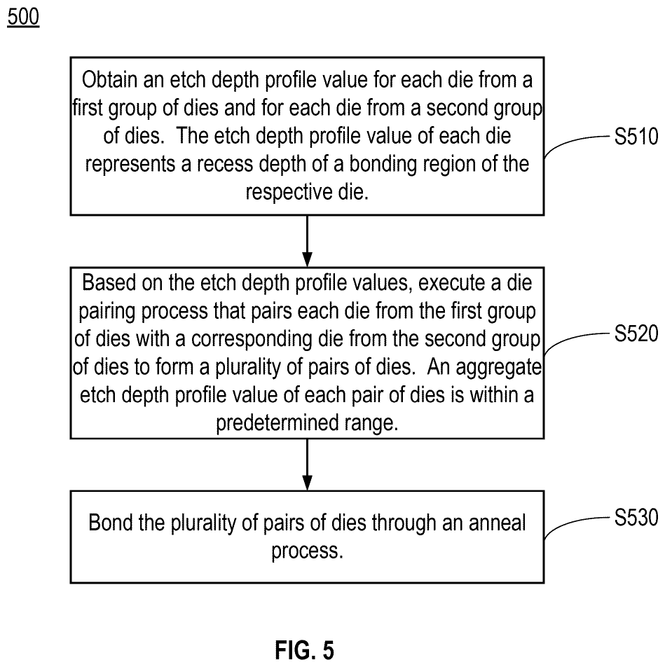

FIG. 5 is a flow chart of an exemplary process 500 of performing a die-to-die bonding according to some embodiments of the present disclosure. In various embodiments, some of the steps of the process 500 shown can be performed concurrently or in a different order than shown, can be substituted by other method steps, or can be omitted. Additional method steps can also be performed as desired.

Starting at S510, the process 500 can obtain an etch depth profile value for each die from a first group of dies and for each die from a second group of dies. The etch depth profile value of each die represents a recess depth of a bonding region of the respective die. Then, the process 500 can proceed to step S520.

At step S520, based on the etch depth profile values, the process 500 can execute a die pairing process that pairs each die from the first group of dies with a corresponding die from the second group of dies to form a plurality of pairs of dies. An aggregate etch depth profile value of each pair of dies is within a predetermined range. Then, the process 500 can proceed to step S530.

At step S530, the process 500 can bond the plurality of pairs of dies through an anneal process. Then, the process 500 can terminate.

Aspects of the disclosure provide a method for a die-to-die bonding of a semiconductor circuit. The method includes accessing a first group of dies sourced from a first wafer. Each die from the first group of dies has a bonding surface that includes a dielectric material and a metal. The metal has been recessed below a surface of the dielectric material as a result of a CMP process. The method further includes accessing a second group of dies sourced from a second wafer. Each die from the second group of dies has a bonding surface that includes a dielectric material and a metal. The metal has been recessed below a surface of the dielectric material as a result of a CMP process. The method further includes identifying a depth profile value for each die from the first group of dies and for each die from the second group of dies. Each depth profile value is based on measurement data. Each depth profile value represents a recess depth of metal relative to the surface of the dielectric layer for each die. The method further includes executing a die pairing process that paired dies from the first group of dies with dies from the second group of dies such that each paired die has an aggregate etch depth profile value within a predetermined range. The method further includes executing an anneal process that bonds the paired dies such that opposing dielectric surfaces of the paired dies bond with each other, and opposing metal within recesses of the paired dies expands and bonds with each other.

In an embodiment, the dies from the first group of dies having comparatively greater depth profile values are paired with the dies from the second group of dies having comparatively lesser depth profile values.

In an embodiment, the method further includes excluding paired dies from the anneal process that have an aggregate etch depth profile value out of the predetermined range.

In an embodiment, process parameters of the anneal process can include time and temperature of the anneal process and are based on aggregate etch depth profile values of a group of paired dies.

In an embodiment, the method further includes identifying the depth profile value for each die based on the measurement data including measuring recess depths of dies across the first wafer and the second wafer.

In an embodiment, the method further includes identifying the depth profile value for each die based on the measurement data including measuring recess depths of dies across one or more representative wafers.

Aspects of the disclosure provide a method for a die-to-die bonding of a semiconductor circuit. The method includes accessing a first group of dies sourced from a first wafer. Each die from the first group of dies has a bonding surface that includes a dielectric material and a metal. The metal has been recessed below a surface of the dielectric material as a result of a CMP process. Dies from the first group of dies have variable recess depths of the metal. The method further includes accessing a second group of dies sourced from a second wafer. Each die from the second group of dies has a bonding surface that includes a dielectric material and a metal. The metal has been recessed below a surface of the dielectric material as a result of a CMP process. Dies from the second group of dies have variable recess depths of the metal. The method further includes pairing the dies from the first group of dies with the dies from the second group of dies such that the combined recess depths of the metal are normalized among the paired dies. The method further includes executing an anneal process that bonds paired dies such that opposing dielectric surfaces of the paired dies bond with each other, and opposing metals within recesses of the paired dies expand and bond with each other.

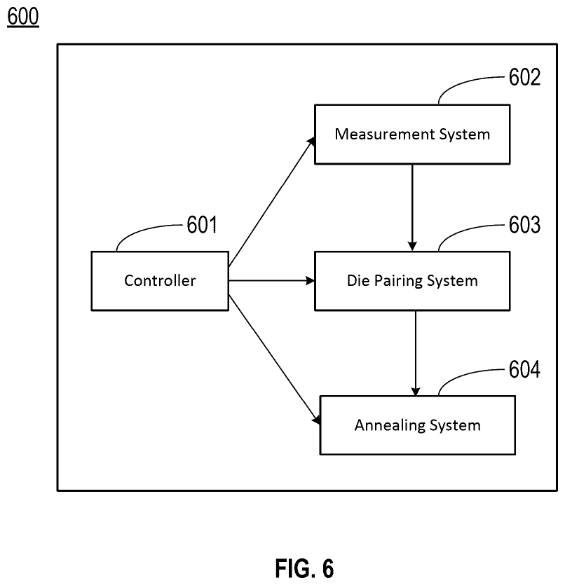

FIG. 6 shows an die-to-die bonding system 600 according to embodiment of the disclosure. The die-to-die bonding system 600 includes a controller 601, a measurement system 602, a die pairing system 603, and an annealing system 604. The measurement system 602 can obtain an etch depth profile value for each die from a first group of dies and for each die from a second group of dies, the etch depth profile value of each die representing a recess depth of a bonding region of the respective die. Based on the etch depth profile values, the die pairing system 603 can execute a die pairing process that pairs each die from the first group of dies with a corresponding die from the second group of dies to form a plurality of pairs of dies, an aggregate etch depth profile value of each pair of dies being within a predetermined range. The annealing system 604 can execute an anneal process to bond the plurality of pairs of dies.

In an embodiment, the die-to-die bonding system can include a wafer dicing system that dices a wafer into a plurality of dices and a die handling system that picks and places the plurality of dies to corresponding positions.

In an embodiment, the controller 601 can control operations of the wafer dicing system, the die handling system, the measurement system 602, the die pairing system 603, and the annealing system 604.

Aspects of the disclosure provide a die-to-die bonding method. The die-to-die bonding method includes obtaining an etch depth profile value for each die from a first group of dies and for each die from a second group of dies, the etch depth profile value of each die representing a recess depth of a bonding region of the respective die; based on the etch depth profile values, executing a die pairing process that pairs each die from the first group of dies with a corresponding die from the second group of dies to form a plurality of pairs of dies, an aggregate etch depth profile value of each pair of dies being within a predetermined range; and bonding the plurality of pairs of dies through an anneal process.

In an embodiment, the bonding region of each die includes a dielectric material and a metal that is recessed below a surface of the dielectric material.

In an embodiment, the recess depth of the bonding region indicates a recess depth of the metal relative to the surface of the dielectric material of the bonding region.

In an embodiment, the die pairing process includes pairing a first die having a first etch depth profile value that is greater than an etch depth profile value threshold with a second die having a second etch depth profile value that is less than the etch depth profile value threshold, the first and second dies being from the first and second group of dies, respectively.

In an embodiment, the die pairing process is executed based on the etch depth profile values being input into an artificial intelligence model that is trained to pair the dies from the first group of dies with the dies from the second group of dies such that the aggregate etch depth profile value of each pair of dies is within the predetermined range.

In an embodiment, the bonding the plurality of pairs of dies includes: placing the plurality of pairs of dies such that the bonding region of one die of each pair of dies is opposed to the bonding region of the other die of the respective pair of dies; and adjusting parameters of the anneal process such that the opposed bonding regions of each pair of dies are bonded with each other.

In an embodiment, the parameters of the anneal process include time and temperature.

In an embodiment, the parameters of the anneal process are adjusted based on the aggregate etch depth profile values of a subset of the plurality of pairs of dies.

In an embodiment, the first and second groups of dies are from first and second wafers, respectively.

In an embodiment, the etch depth profile value for each die is obtained by measuring the recess depths of the bonding regions of dies across the first wafer and the second wafer.

Aspects of the disclosure provide a die-to-die bonding system. The die-to-die bonding system includes a controller configured to control a measurement system to obtain an etch depth profile value for each die from a first group of dies and for each die from a second group of dies, the etch depth profile value of each die representing a recess depth of a bonding region of the respective die; based on the etch depth profile values, control a die pairing system to execute a die pairing process that pairs each die from the first group of dies with a corresponding die from the second group of dies to form a plurality of pairs of dies, an aggregate etch depth profile value of each pair of dies being within a predetermined range; and control an annealing system to execute an anneal process to bond the plurality of pairs of dies.

In an embodiment, the bonding region of each die includes a dielectric material and a metal that is recessed below a surface of the dielectric material.

In an embodiment, the recess depth of the bonding region indicates a recess depth of the metal relative to the surface of the dielectric material of the bonding region.

In an embodiment, the die pairing process includes pairing a first die having a first etch depth profile value that is greater than an etch depth profile value threshold with a second die having a second etch depth profile value that is less than the etch depth profile value threshold, the first and second dies being from the first and second group of dies, respectively.

In an embodiment, the die pairing process is executed based on the etch depth profile values being input into an artificial intelligence model that is trained to pair the dies from the first group of dies with the dies from the second group of dies such that the aggregate etch depth profile value of each pair of dies is within the predetermined range.

In an embodiment, the bonding the plurality of pairs of dies includes: placing the plurality of pairs of dies such that the bonding region of one die of each pair of dies is opposed to the bonding region of the other die of the respective pair of dies; and adjusting parameters of the anneal process such that the opposed bonding regions of each pair of dies are bonded with each other.

In an embodiment, the parameters of the anneal process include time and temperature.

In an embodiment, the parameters of the anneal process are adjusted based on the aggregate etch depth profile values of a subset of the plurality of pairs of dies.

In an embodiment, the first and second groups of dies are from first and second wafers, respectively.

In an embodiment, the etch depth profile value for each die is obtained by measuring the recess depths of the bonding regions of dies across the first wafer and the second wafer.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A die-to-die bonding method, comprising:
obtaining an etch depth profile value for each die from a first group of dies and for each die from a second group of dies, the etch depth profile value of each die representing a recess depth of a bonding region of the respective die;
based on the etch depth profile values, executing a die pairing process that pairs each die from the first group of dies with a corresponding die from the second group of dies to form a plurality of pairs of dies, an aggregate etch depth profile value of each pair of dies being within a predetermined range; and
bonding the plurality of pairs of dies through an anneal process.

2. The die-to-die bonding method of claim 1, wherein the bonding region of each die includes a dielectric material and a metal that is recessed below a surface of the dielectric material.

3. The die-to-die bonding method of claim 2, wherein the recess depth of the bonding region indicates a recess depth of the metal relative to the surface of the dielectric material of the bonding region.

4. The die-to-die bonding method of claim 1, wherein the die pairing process includes:
pairing a first die having a first etch depth profile value that is greater than an etch depth profile value threshold with a second die having a second etch depth profile value that is less than the etch depth profile value threshold, the first and second dies being from the first and second group of dies, respectively.

5. The die-to-die bonding method of claim 1, wherein the die pairing process is executed based on the etch depth profile values being input into an artificial intelligence model that is trained to pair the dies from the first group of dies with the dies from the second group of dies such that the aggregate etch depth profile value of each pair of dies is within the predetermined range.

6. The die-to-die bonding method of claim 1, wherein the bonding the plurality of pairs of dies includes:
placing the plurality of pairs of dies such that the bonding region of one die of each pair of dies is opposed to the bonding region of the other die of the respective pair of dies; and
adjusting parameters of the anneal process such that the opposed bonding regions of each pair of dies are bonded with each other.

7. The die-to-die bonding method of claim 6, wherein the parameters of the anneal process include time and temperature.

8. The die-to-die bonding method of claim 6, wherein the parameters of the anneal process are adjusted based on the aggregate etch depth profile values of a subset of the plurality of pairs of dies.

9. The die-to-die bonding method of claim 1, wherein the first and second groups of dies are from first and second wafers, respectively.

10. The die-to-die bonding method of claim 9, wherein the etch depth profile value for each die is obtained by measuring the recess depths of the bonding regions of dies across the first wafer and the second wafer.

11. A die-to-die bonding system, comprising:
a controller configured to
control a measurement system to obtain an etch depth profile value for each die from a first group of dies and for each die from a second group of dies, the etch depth profile value of each die representing a recess depth of a bonding region of the respective die,
based on the etch depth profile values, control a die pairing system to execute a die pairing process that pairs each die from the first group of dies with a corresponding die from the second group of dies to form a plurality of pairs of dies, an aggregate etch depth profile value of each pair of dies being within a predetermined range, and
control an annealing system to execute an anneal process to bond the plurality of pairs of dies.

12. The die-to-die bonding system of claim 11, wherein the bonding region of each die includes a dielectric material and a metal that is recessed below a surface of the dielectric material.

13. The die-to-die bonding system of claim 12, wherein the recess depth of the bonding region indicates a recess depth of the metal relative to the surface of the dielectric material of the bonding region.

14. The die-to-die bonding system of claim 11, wherein the die pairing process includes:
pairing a first die having a first etch depth profile value that is greater than an etch depth profile value threshold with a second die having a second etch depth profile value that is less than the etch depth profile value threshold, the first and second dies being from the first and second group of dies, respectively.

15. The die-to-die bonding system of claim 11, wherein the die pairing process is executed based on the etch depth profile values being input into an artificial intelligence model that is trained to pair the dies from the first group of dies with the dies from the second group of dies such that the aggregate etch depth profile value of each pair of dies is within the predetermined range.

16. The die-to-die bonding system of claim 11, wherein the controller is configured to:
control the die pairing system to place the plurality of pairs of dies such that the bonding region of one die of each pair of dies is opposed to the bonding region of the other die of the respective pair of dies; and
control the annealing system to adjust parameters of the anneal process such that the opposed bonding regions of each pair of dies are bonded with each other.

17. The die-to-die bonding system of claim 16, wherein the parameters of the anneal process include time and temperature.

18. The die-to-die bonding system of claim 16, wherein the parameters of the anneal process are adjusted based on the aggregate etch depth profile values of a subset of the plurality of pairs of dies.

19. The die-to-die bonding system of claim 11, wherein the first and second groups of dies are from first and second wafers, respectively.

20. The die-to-die bonding system of claim 19, wherein the etch depth profile value for each die is obtained by measuring the recess depths of the bonding regions of dies across the first wafer and the second wafer.
